(19) United States
(12) Patent Application Publication
(10) Pub. No.: US 2004/0129453 A1
(43) Pub. Date: Jul. 8, 2004

(54) Electronic substrate with direct inner layer component interconnection

(76) Inventors: David W. Boggs, Hillsboro, OR (US); Daryl Sato, Portland, OR (US); John Dungan, Hillsboro, OR (US)

Correspondence Address: Paul J. Fordenbacher, Schwabe Williamson & Wyatt, Suite 1900, 1211 SW Fifth Avenue, Portland, OR, 97204, US

(21) Appl. No.: 10/337,949

(22) Filed: Jan. 7, 2003

(51) Int. Cl. H05K 1/11; H01R 12/04

(52) U.S. Cl. 174/261

(57) ABSTRACT

Embodiments of substrate in accordance with the present invention provide interconnect cavities for direct interconnection between SMT components and internal conductive inner layers, as well as surface outer layers. Interconnect cavities eliminate the need for through hole vias and require less substrate surface area and internal volume. Each interconnect cavity comprises a cavity extending from the substrate surface to an adjacent internal conductive inner layer directly beneath the cavity. The cavity extends through a conductive outer layer on the substrate surface. The cavity has a conductive liner interconnected with the outer layer and the inner layer forming a cup-shaped conductive depression interconnecting the outer layer with the inner layer.

### FIELD OF THE INVENTION

The present invention relates to microelectronic assemblies and, more particularly, to substrate and methods for providing electrical interconnects to facilitate high-performance and high-density component interconnection.

### BACKGROUND OF INVENTION

It is common that electrical assemblies comprise at least one substrate that is used as a structural platform as well as to electrically interconnect one electrical component with another. The substrate is commonly a relatively rigid panel that comprises a variety of electrical interconnects that run through, within, and/or upon the panel. Examples of substrates include, but are not limited to, printed circuit boards (PCB), motherboards, and carrier substrates within microelectronic packages.

One long-standing method of attachment of an electrical component to the substrate is the well established process of providing the substrate with plated through holes, referred to as vias, through which corresponding pins on the electrical component are inserted, and subsequently soldered from the opposite side of the substrate. Through hole vias are the most economical via type from a substrate manufacturing perspective for providing interconnection between surface mounted components with internal conductive inner layers. With the advent of new manufacturing technologies that do away with the pins on the electrical component, there have been attempts to continue to use the relatively inexpensive through hole via substrates with these pin-less components.

One method of interconnecting electrical components to the substrate, or one substrate to another substrate, incorporates surface mount technology (SMT). The SMT electrical component replaces the pin or wire contacts with simple, flat electrical interconnects known as land pads. Surface mount technology electrical components are widely used because of their compact size and simplicity of interconnection doing away with such issues as pin alignment and bulkiness. Examples of SMT electrical components include, but are not limited to, flip chip-ball grid array (FC-BGA) packaging and chip-scale packaging.

FIG. 1 is a top view of a substrate 10 which comprises a plurality of SMT bond pads 20 on the surface 11 of the substrate 10 adjacent to a corresponding through hole via 24 and electrically interconnected therewith with a link 22. FIG. 2 is a cross-sectional view of the substrate 10 showing the interconnection of surface components with the plated through hole via 26 extending through the thickness of the substrate 10. The plated through hole via 26 is interconnected with a plurality of internal conductive inner layers 28. A SMT component 30 is shown interconnected to the SMT bond pads 20 with reflowable electrical interface material 32, shown here as a solder ball.

Providing the bond pad 20 and link 22, as well as the through hole via 26, for each interconnection takes up a considerable amount of area on the surface 11 of the substrate 10. This limits the number of interconnections that a substrate 10 can provide. Further, the intrusion into the thickness of the substrate 10 of the through hole via 26 limits the available volume within the substrate 10 that can be used to provide inner layer interconnections 28, and increases the complexity of substrate design regarding placement of those interlayer interconnections 28.

Improvements are needed for providing a substrate providing interconnection with inner layers by SMT components while reducing the surface area required for such interconnections. Further, the substrate should provide greater internal conductive inner layer density by eliminating the overly invasive through hole via.

### BRIEF DESCRIPTION OF DRAWINGS

FIG. 1 is a top view of a substrate which comprises a plurality of SMT bond pads on the surface of the substrate adjacent to a corresponding through hole via and electrically interconnected therewith with a link;

FIG. 2 is a cross-sectional view of the substrate showing the interconnection of surface components with the plated through hole via extending through the thickness of the substrate; and

FIGS. 3 and 4 are top and cross-sectional views of a substrate which comprises a plurality of interconnect cavities, in accordance with an embodiment of the present invention.

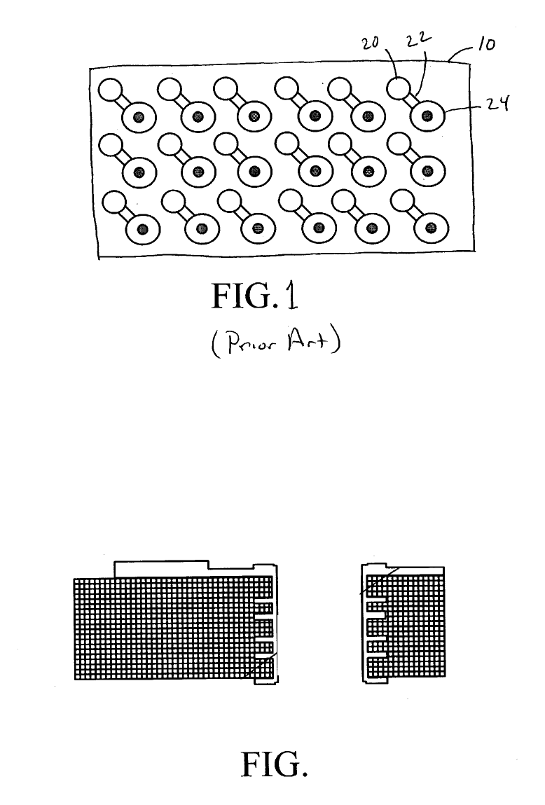

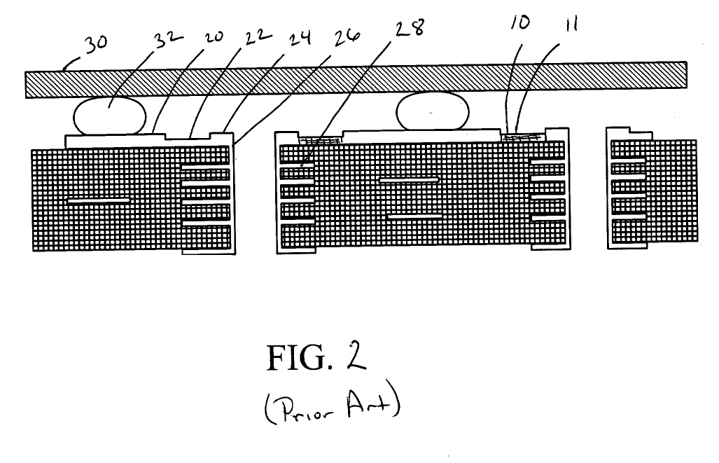

### DESCRIPTION

In the following detailed description, reference is made to the accompanying drawings which form a part hereof wherein like numerals designate like parts throughout, and in which is shown by way of illustration specific embodiments in which the invention may be practiced. It is to be understood that other embodiments may be utilized and structural or logical changes may be made without departing from the scope of the present invention. Therefore, the following detailed description is not to be taken in a limiting sense, and the scope of the present invention is defined by the appended claims and their equivalents.

Embodiments of substrate in accordance with the present invention provide interconnect cavities for direct interconnection between SMT components and internal conductive inner layers, as well as surface outer layers. Interconnect cavities eliminate the need for through hole vias and require less substrate surface area and internal volume.

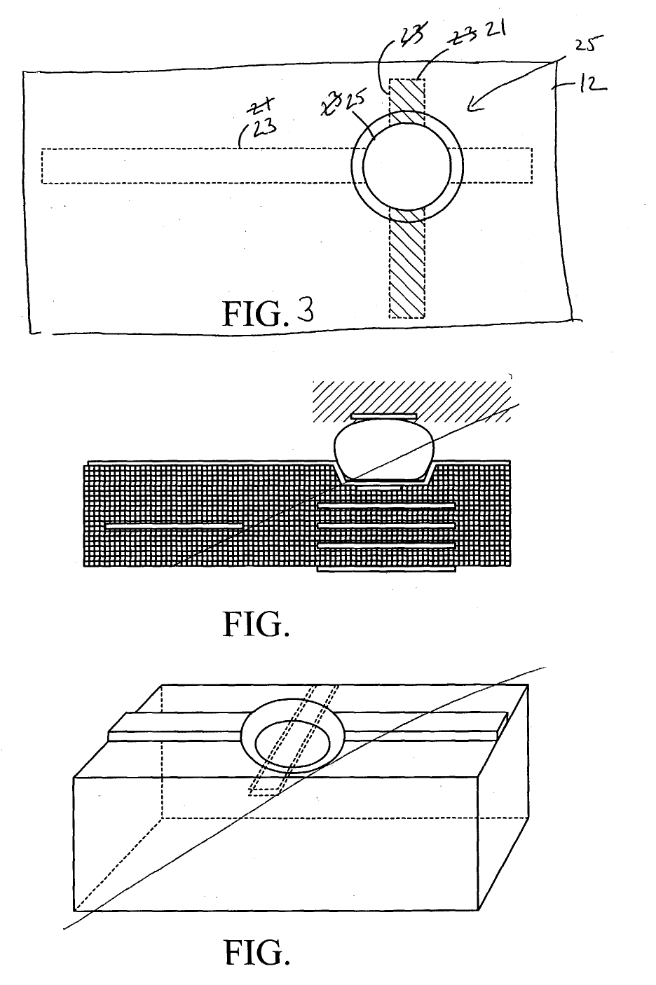

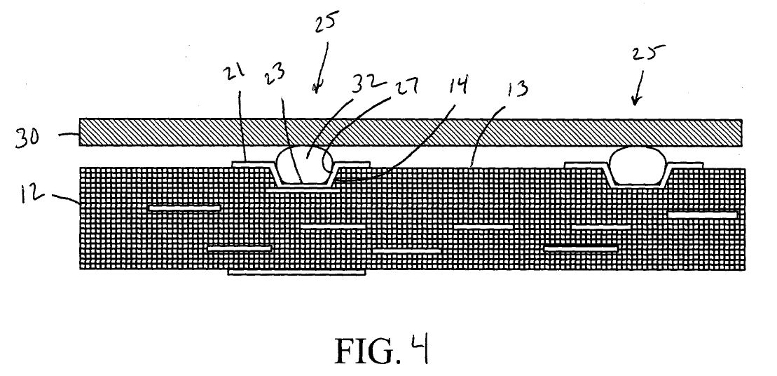

FIGS. 3 and 4 are top and cross-sectional views of a substrate 12 which comprises a plurality of interconnect cavities 25, in accordance with an embodiment of the present invention. The substrate 12 is provided with multiple conductive inner layers 23 and outer layers 21 using well known fabrication techniques for circuit board fabrication, such as, but not limited to, lamination stacking.

Each interconnect cavity 25 comprises a cavity 14 extending from the substrate surface 13 to an adjacent internal conductive inner layer 23 directly beneath the cavity 14. The cavity 14 extends through a conductive outer layer 21 on the substrate surface 13. The cavity 14 has a conductive liner 27 interconnected with the outer layer 21 and the inner layer 23 forming a cup-shaped conductive depression interconnecting the outer layer 21 with the inner layer 23.

The conductive outer layer 21 can comprise a conductive trace as shown in FIG. 3, a conductive pad (not shown), among other configurations. A conductive trace outer layer 21 provides interconnection with other outer layers 21. A conductive pad outer layer 21 isolates the interconnect cavity 25 from other outer layers 21.

The cavity 14 is formed using known techniques currently being used to produce blind vias. In embodiments in accordance with methods of the present invention, liquid photoimageable resists and laser direct imaging are used to produce the cavity 14. The cavity 14 is provided with a conductive liner 27 using known techniques, including plating and vapor deposition, among others.

A SMT component 30 is interconnected with the interconnect cavity 25 using well-known reflow processes. For example, but not limited thereto, each of plurality of land pads 33 on the surface of the SMT component 30 is provided with electrically conductive reflowable interconnect material 32, shown in FIG. 4 as a solder ball. Each land pad 33 is registered with a corresponding interconnect cavity 25 with the interconnect material 32 positioned into the interconnect cavity 25. The assembly undergoes a reflow process interconnecting the land pads 33 with the interconnect cavities 25.

In other embodiments, the interconnect material 32 is placed within the interconnect cavity 25 prior to interconnection with the land pads 33. Conductive paste and adhesive, among others, can be used to interconnect the land pads 33 with the interconnect cavity 25.

Substrate provided in accordance with embodiments of the present invention provides direct inner layer component attachment using interconnect cavities. Compared with through hole vias, interconnect cavities consume less substrate surface allowing for higher interconnect density substrate, or smaller substrate with the same number of interconnects. Interconnect cavities do not extend through the substrate and therefore consume less inter-substrate volume, allowing for higher inner layer densities and easier accommodation of inner layer orientations.

Although specific embodiments have been illustrated and described herein for purposes of description of the preferred embodiment, it will be appreciated by those of ordinary skill in the art that a wide variety of alternate and/or equivalent implementations calculated to achieve the same purposes may be substituted for the specific embodiment shown and described without departing from the scope of the present invention. Those with skill in the art will readily appreciate that the present invention may be implemented in a very wide variety of embodiments. This application is intended to cover any adaptations or variations of the embodiments discussed herein. Therefore, it is manifestly intended that this invention be limited only by the claims and the equivalents thereof.

What is claimed is:

1. An electronic substrate for interconnecting electronic components, comprising:
a substrate having a plurality of conductive inner layers and conductive outer layers; and
one or more interconnect cavities electrically interconnected with one or more outer layers and one or more inner layers.

2. The electronic substrate of claim 1, wherein each interconnect cavity comprises:
a cavity extending from corresponding inner and outer layers, the cavity having a conductive liner interconnected with the inner and outer layers.

3. The electronic substrate of claim 1, wherein each interconnect cavity is adapted to receive and interconnect with reflowable electrically conductive interconnect material.

4. The electronic substrate of claim 3, wherein the interconnect cavities are positioned to correspond with land pads of a surface mount technology electrical component.

5. The electronic substrate of claim 1, wherein each interconnect cavity is adapted to receive and interconnect with reflowable electrically conductive interconnect material.

6. A method for making a substrate for interconnecting electronic components, comprising:
providing a substrate having a plurality of electrically conductive inner and outer layers;
forming a cavity between one or more inner layer and one or more outer layer;
depositing an electrically conductive liner in the cavity interconnected with the corresponding inner and outer layers.

7. The method of claim 6, wherein forming a cavity between one or more inner layer and one or more outer layer comprises:
using a laser to form a cavity between one or more inner layer and one or more outer layer.

8. The method of claim 6, wherein forming a cavity between one or more inner layer and one or more outer layer comprises:
using a resist mask and an etching process to etch a cavity between one or more inner layer and one or more outer layer.

9. The method of claim 6, wherein depositing an electrically conductive liner in the cavity interconnected with the corresponding inner and outer layers comprises:
electroplating a layer of conductive material on the cavity walls and interconnected with the corresponding inner and outer layers.

10. The method of claim 6, wherein depositing an electrically conductive liner in the cavity interconnected with the corresponding inner and outer layers comprises:
using a vapor deposition process to form a layer of conductive material on the cavity walls and interconnected with the corresponding inner and outer layers.

11. An electronic device, comprising:
an electronic component having component interconnects; and
an electronic substrate comprising:
a substrate having a plurality of conductive inner layers and conductive outer layers; and
one or more interconnect cavities electrically interconnected with one or more outer layers and one or more inner layers, the component interconnects interconnected with the interconnect cavities.

12. The electronic device of claim 11, wherein each interconnect cavity comprises:
a cavity extending from corresponding inner and outer layers, the cavity having a conductive layer interconnected with the inner and outer layers.

13. The electronic device of claim 11, further comprising reflowable electrically conducting interconnect material, wherein each component interconnect and corresponding interconnect cavity is interconnected with the reflowable electrically conductive interconnect material.

14. The electronic device of claim 11, wherein the interconnect cavities are positioned to correspond with the component interconnects.

15. The electronic device of claim 11, wherein the electronic component is a microelectronic die.
